(19) United States
(12) Patent Application Publication
(10) Pub. No.: US 2003/0231127 A1
(43) Pub. Date: Dec. 18, 2003

(54) Signal processing system and method

(75) Inventor: Marcus Richard Jones, Lincoln (GB)

Correspondence Address: James M. Bagarazzi, DORITY & MANNING, P.A., P.O. Box 1449, Greenville, SC, 29602, US

(73) Assignee: Zarlink Semiconductor Limited

(21) Appl. No.: 10/458,767

(22) Filed: Jun. 12, 2003

(30) Foreign Application Priority Data
Jun. 12, 2002 (GB) 0213503.6

(51) Int. Cl. H03M 1/66

(52) U.S. Cl. 341/144

(57) ABSTRACT

A data processing system is disclosed including a data processor for operating on data samples received from a data source, a digital to analog converter arranged to receive the data samples from the data processor and to convert the received data samples into an analog signal, and a controller arranged to monitor the magnitude of the data samples received from the data source and disable one or both of the data processor means and the digital to analog converter when the magnitude of one or more received data samples falls within a predetermined magnitude range. Such a system is able to operate in a low-power mode that may be advantageous for battery-powered device or other applications where power conservation is important.

### CROSS-REFERENCE TO RELATED APPLICATIONS

The present application claims priority to currently pending United Kingdom Patent Application number 0213503.6, filed Jun. 12, 2002.

### STATEMENT REGARDING FEDERALLY SPONSORED RESEARCH OR DEVELOPMENT

N/A

### BACKGROUND OF THE INVENTION

This invention relates to a signal processing system, and particularly, though not exclusively to a data processing system for processing data samples representing audible sound.

Signal processing systems are well known for use in many applications. For example, a digital sound receiving system may include a data processing system used to receive data samples, representing an audio-frequency signal, from a sound transmission system via some link.

FIG. 1 shows a known receiving system that can be used for outputting audio data. The receiving system comprises a transmission medium interface (TMI) 1, a buffer 3, and a CODEC 4 which is made up of a digital interface 5, a digital signal processor (DSP) stage 7, a digital to analog converter (DAC) 9, an amplifier 11, and a speaker 13. Audio data samples are received from a data link to the TMI 1 that passes each sample to the buffer 3 wherein the samples are stored for subsequent processing by the CODEC 4. Once ready for processing, each data sample is passed to the DSP stage 7 of the CODEC 4, via the digital interface 5. The DSP stage 7 is usually configured to perform gain and filtering operations on the samples. The DAC 9 then converts the samples to analog form and the resultant signal is passed to the amplifier 11, the gain of which determines the amplitude at which the signal is output through the speaker 13.

In electrical or electronic systems, it is desirable to reduce the amount of consumed power.

### OBJECTS AND SUMMARY OF THE INVENTION

According to one aspect of the invention, there is provided a signal processing system, comprising: means arranged to receive a signal; signal processing means for conditioning a signal received by the receiving means; and control means arranged to (a) monitor the magnitude of a signal received by the receiving means; and (b) to disable the signal processing means when the magnitude of the received signal falls within a predetermined magnitude range. The signal processing system can be applied to both analog and digital signals.

It will be appreciated that the power used by the system can be reduced by disabling one or more components when a received signal is within a predetermined magnitude range, e.g. below a predetermined threshold amplitude. It will be appreciated that sound signals, and so digitized samples representative thereof, can vary about a zero level. Accordingly, the absolute value of the amplitude, i.e. the magnitude is of interest, at least in relation to audio devices.

Such a system can thus be effectively operated in a ‘low-power’ mode, which may be useful for battery-powered devices, as well as other applications where power conservation is desirable.

According to a second aspect of the invention, there is provided a data processing system comprising: data processing means for operating on data samples received from a data source; digital to analog conversion means arranged to receive the data samples from the data processing means and to convert the received data samples into an analog signal; and control means arranged to (a) monitor the magnitude of the data samples received from the data source, and (b) to disable one or both of the data processing means and the digital to analog conversion means when the magnitude of one or more received data samples falls within a predetermined magnitude range.

The data processing system may further comprise output transducer means arranged to receive the analog signal from the digital to analog conversion means thereby to generate audible sound at a controllable output amplitude.

Prior to disabling one or both of the data processing means and the digital to analog conversion means, the control means can be arranged to reduce the output amplitude of the output transducer means. In this way, audible artifacts resulting from the disabling operation of the control means can be inhibited by reducing the output amplitude of the transducer before disabling occurs. It will be appreciated that disabling, which can be done in a number of ways, e.g. by powering-down a processing device, can cause audible ‘clicks’ on a transducer means connected downstream from the processing device.

The output amplitude of the output transducer may be controlled by means of an amplifier; the control means being arranged to reduce the output amplitude by reducing the gain of the amplifier.

The control means may be arranged to disable one or both of the data processing means and the digital to analog Conversion means when the magnitude of received data samples falls within a predetermined magnitude range over a predetermined time period.

The control means can be further arranged to re-enable one or both of the data processing means and the digital to analog conversion means when the magnitude of received data samples falls outside the predetermined magnitude range over the predetermined time period.

The control means is preferably arranged such that the predetermined time period mentioned above is greater than the time period required to disable one or both of the data processing means and the digital to analog conversion means.

The control means may be arranged to disable one or both of the processing means and the digital to analog conversion means by means of disabling a clocking signal fed to the or each respective means. The control means can be further arranged to disable the supply of electrical power to the, or each, respective means after disabling the clocking signal(s).

According to a third aspect of the invention, there is provided an adaptive data processing method in a data processing system including digital to analog conversion means and data processing means for operating on data received by the digital to analog conversion means, the method comprising: monitoring the magnitude of data samples received from a data source; and disabling one or both of the digital to analog conversion means and the data processing means when the magnitude of the received signal falls within a predetermined magnitude range.

According to a fourth aspect of the invention, there is provided a computer program comprising computer readable instructions stored on a computer-usable medium, the computer program being arranged to perform an adaptive data processing method in a data processing system including digital to analog conversion means and data processing means for operating on data received by the digital to analog conversion means, the method comprising: monitoring the magnitude of data samples received from a data source; and disabling one or both of the digital to analog conversion means and the data processing means when the magnitude of the received signal falls within a predetermined magnitude range.

Additional objects and advantages of the invention will be set forth in part in the description that follows, and in part will be obvious from the description, or may be learned by practice of the invention. The objects and advantages of the invention may be realized and attained by means of the instrumentalities and combinations particularly pointed out in the appended claims.

The accompanying drawings, which are incorporated in and constitute a part of this specification, illustrate at least one presently preferred embodiment of the invention as well as some alternative embodiments. These drawings, together with the description, serve to explain the principles of the invention but by no means are intended to be exhaustive of all of the possible manifestations of the invention.

### BRIEF DESCRIPTION OF THE DRAWINGS

FIG. 1 is a block diagram of a known data receiving system;

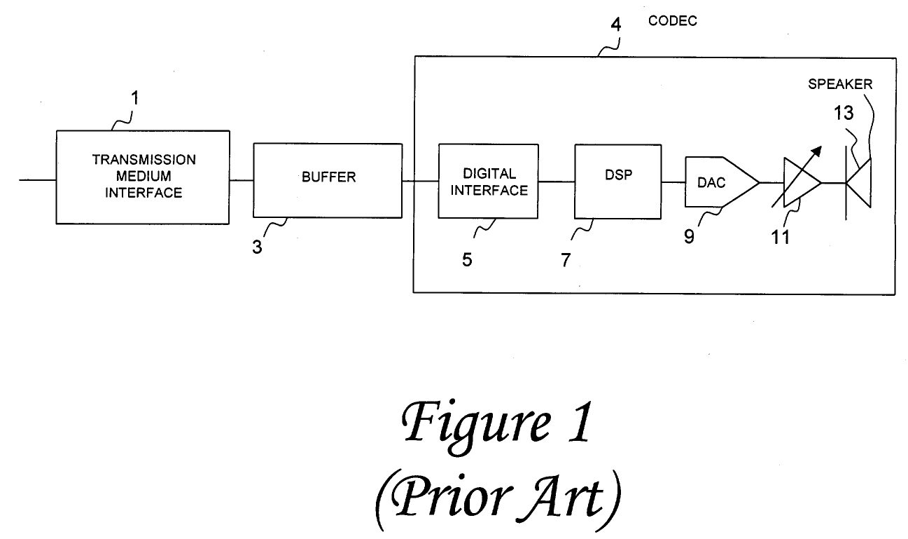

FIG. 2 is a block diagram of a data receiving system according to the invention; and

FIG. 3 is a flow diagram showing the steps of an algorithm used by a control system part of the data receiving system of FIG. 2.

### DETAILED DESCRIPTION OF THE PREFERRED EMBODIMENTS

Reference now will be made in detail to the presently preferred embodiments of the invention, one or more examples of which are illustrated in the accompanying drawings. Each example is provided by way of explanation of the invention, which is not restricted to the specifics of the examples. In fact, it will be apparent to those skilled in the art that various modifications and variations can be made in the present invention without departing from the scope or spirit of the invention. For instance, features illustrated or described as part of one embodiment, can be used on another embodiment to yield a still further embodiment. Thus, it is intended that the present invention cover such modifications and variations as come within the scope of the appended claims and their equivalents. The same numerals are assigned to the same components throughout the drawings and description.

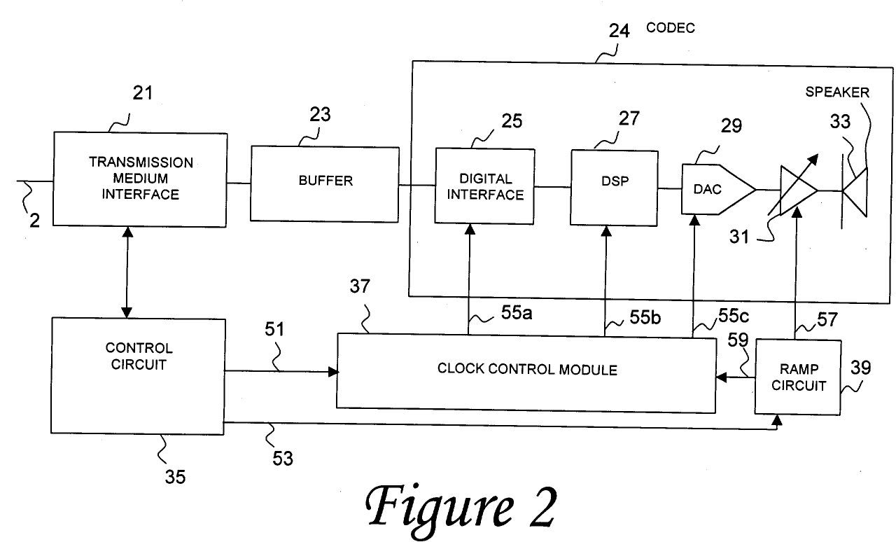

Referring to FIG. 2, a data receiving system configured to receive and process sound samples for audible output comprises a TMI 21, a buffer 23, and a CODEC 24. The TMI 21 receives data samples, representing an audible sound signal, from a data link 2, and passes the samples to the buffer 23 wherein the samples are stored for subsequent transmission to the CODEC 24. The CODEC 24 comprises a digital interface 25, which receives the samples from the buffer 23 and passes them to a DSP stage 27 wherein conditioning of the signal is performed, for example, filtering and gain operations. The samples are passed from the DSP stage 27 to an ADC 29 that generates an analog signal from the received samples, the analog signal being inputted to a speaker 33 via a controllable amplifier 31. The amplitude of the analog audio signal outputted from the speaker 33, and so its audible volume, is dependant on the gain of the controllable amplifier 31.

A clock control module (CCM) 37 is also provided, the CCM being arranged to provide clocking signals and power to the digital interface 25, the DSP stage 27 and the DAC 29 on respective control lines 55a-c. A ramp circuit 39 is also provided, the ramp circuit being arranged to control the gain of the controllable amplifier 31 by means of a line 57. The ramp circuit 39 is also connected to the CCM 37 for reasons that will be explained below.

A control circuit 35 is connected to the TMI 21 and is arranged to receive incoming the data samples from the data link 2. In addition, the control circuit 35 is arranged to adaptively control the operation of the CODEC 24 in accordance with the magnitude of the samples received from the TMI 21. In order to perform this, the control circuit 35 is connected to the CCM 37, by a line 51, and arranged such that the respective clocking signals and power supply to the digital interface 25, the DSP stage 27 and the DAC 29 are inhibited when incoming samples (to the TMI 21) have a magnitude falling within a particular range, namely below a predetermined magnitude. The control circuit 35 effectively enters a ‘low-power’ mode in this situation.

The control circuit 35 is also connected to the ramp circuit 39 so that the gain of the controllable amplifier 31 is reduced when the incoming samples have a magnitude falling below the above-mentioned predetermined magnitude. As will be explained below, this is desirable since the step of inhibiting the clocking signals and power to the digital interface 25, the DSP stage 27 and the DAC 29 can result in an audible ‘clicking’ noise being outputted through the speaker 33. This can be annoying to listeners.

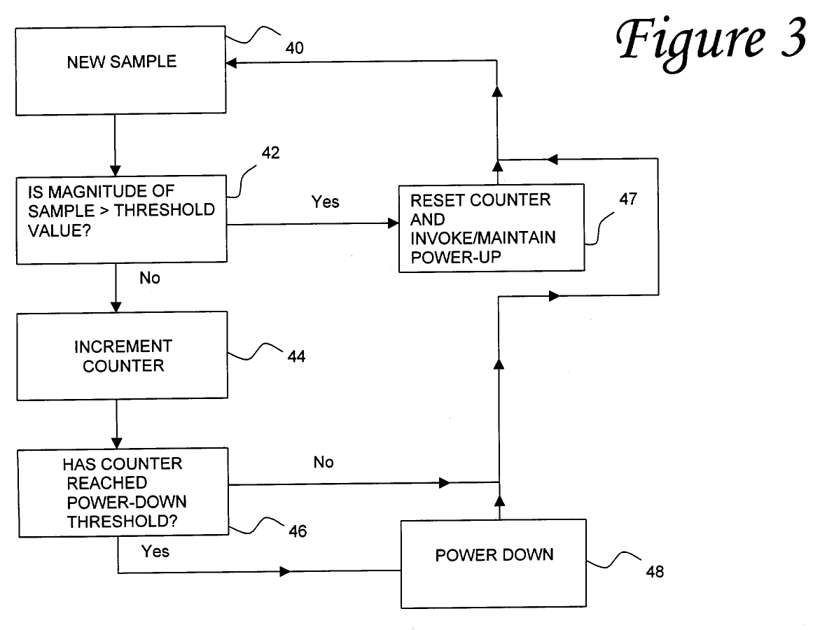

The algorithm by which the control circuit 35 operates will now be described with reference to FIG. 3. In an initial step (step 40), when a sample is received from the TMI 21, its magnitude is compared against a predetermined threshold in a further step 42. Note that, in this sense, the magnitude of the sample will be representative of the instantaneous magnitude of the analog audio signal from which the sample is taken. If the magnitude of the sample is below the predetermined threshold, e.g. because there was little or no sound recorded, then in step 44, a counter (not shown) is incremented. If the magnitude of the sample is equal to, or above, the predetermined threshold, the counter is reset to zero (if not already at zero) and clocking and power is maintained to the digital interface 25, the DSP stage 27 and the DAC 29 (step 47). The next sample is then awaited in initial step 40 again.

Returning to the case where the magnitude of a sample is below the predetermined threshold, after the counter is incremented, it is determined whether the current value of the counter has reached a predetermined value (step 46). As will become clear below, the control circuit 35 is configured to enter the low-power mode only if successive incoming samples are below the predetermined threshold over a predetermined time interval. This ensures that relatively short ‘lulls’ in the magnitude of receives samples does not cause the low-power mode to be entered. Indeed, the predetermined time interval is set so as to be longer than the time taken for either the low-power mode to be entered or exited. Otherwise, by the time each clocking signal and power is inhibited to the CODEC 24, a valid high-magnitude sample may have been received.

The predetermined time interval is established by setting the counter at an appropriate count number. If the predetermined value is not reached in step 46, the next sample is awaited in the initial step 40, and again, the process repeats as above. If the predetermined value is reached in step 46, the low-power mode is entered (step 48).

In the low-power mode (step 48), the clocking signals to the digital interface 25, the DSP stage 27 and the DAC 29 are inhibited by sending a control signal from the control circuit 35 to the CCM 37 over line 51. This will cause the output from the DAC 29 to be at, or close to, mid-rail (i.e. zero volts). Next, a further control signal is sent from the control circuit 35 to the ramp circuit 39 over a line 53. As a result, the ramp circuit is arranged to ‘ramp-down’ the gain of the controllable amplifier 31 by means of a gain control signal transmitted over line 57. Finally, once the gain of the controllable amplifier 31 is low, a ‘power down’ control signal is sent from the ramp circuit 39 to the CCM 37 over a line 59. This causes the power supply to the digital interface 25, the DSP stage 27 and the DAC 29 to be cut. However, as will be appreciated, this power down operation will not result in audible artifacts being outputted from the speaker 33 since the low amplifier gain ensures the volume from the speaker is also low.

Accordingly, as a result of receiving a ‘gap’ (i.e. a period of zero or low magnitude) in a signal, the power consumption of the data receiving system can be reduced.

Once the low-power mode is entered, the next sample is awaited in initial step 40. Clearly, in step 42, if it is determined that subsequent samples are still below the threshold value, the low-power mode is maintained. If a sample is received that is above the threshold value, a ‘power-up’ mode is entered. This occurs in step 47 by means of the counter being reset, and suitable control signals being sent from the control circuit 35, to the CCM 37 and the ramp circuit 39. Specifically, the ramp circuit 39 is controlled so as to ‘ramp-up’ the gain of the controllable amplifier 31 so that the output volume of the speaker 33 is returned to its previous value. Next, power and the clocking signals are supplied to the digital interface 25, the DSP stage 27 and the DAC 29.

After the power-up mode (step 47) is complete, the next sample is awaited in initial step 40.

Note that the size of the buffer 23 is preferably arranged so that it is able to store at least the number of samples corresponding to the predetermined time interval over which successive low magnitude samples will cause a low-power mode to be entered. In this case, the low-power mode can be entered immediately (as described above). Also, the size of the buffer 23 is preferably arranged such that the incoming sample that causes the power-up mode to be entered is available for transfer to the CODEC 24 after the power-up mode is complete.

The above-described data receiving system is useful in many applications wherein available power is an issue. For example, in battery-operated devices, it is desirable to conserve battery power. Accordingly, when data is received having little or no magnitude, it would be desirable to enter the low-power mode. The data receiving system could be applied to a mobile telephone, for example, as well as with Bluetooth devices and voice over IP (VOIP) devices.

While at least one presently preferred embodiment of the invention has been described using specific terms, such description is for illustrative purposes only, and it is to be understood that changes and variations may be made without departing from the spirit or scope of the following claims.

What is claimed is:

1. A signal processing system, comprising:
a signal receiver,
a signal processor, and
a controller configured to (a) monitor the magnitude of a signal received by the signal receiver, and (b) disable the signal processor when the magnitude of the received signal falls within a predetermined magnitude range.

2. A data processing system comprising:
a data processor for operating on data samples received from a data source,
a digital to analog converter configured to receive the data samples from the data processor and to convert the received data samples into an analog signal, and
a controller configured to (a) monitor the magnitude of the data samples received from the data source, and (b) disable one or both of the data processor and the digital to analog converter when the magnitude of one or more received data samples falls within a predetermined magnitude range.

3. A data processing system according to claim 2, further comprising an output transducer configured to receive the analog signal from the digital to analog converter thereby to generate audible sound at a controllable output amplitude.

4. A data processing system according to claim 3, wherein the controller is configured to reduce the output amplitude of the output transducer prior to disabling one or both of the data processor and the digital to analog converter.

5. A data processing system according to claim 4, wherein the output amplitude of the output transducer is controlled by an amplifier, the controller being configured to reduce the output amplitude by reducing the gain of the amplifier.

6. A data processing system according to claim 5, wherein the controller is configured to disable one or both of the data processor and the digital to analog converter when the magnitude of received data samples falls within a predetermined magnitude range over a predetermined time period.

7. A data processing system according to claim 6, wherein the controller is further configured to re-enable one or both of the data processor and the digital to analog converter when the magnitude of received data samples falls outside the predetermined magnitude range over the predetermined time period.

8. A data processing system according to claim 6, wherein the controller is configured such that the predetermined time period is greater than the time period required to disable one or both of the data processor and the digital to analog converter.

9. A data processing system according to claim 2, wherein the controller is configured to disable a clocking signal to one or both of the processor and the digital to analog converter in order to disable one or both of the processor and the digital to analog converter.

10. A data processing system according to claim 9, wherein the controller is further configured to disable the supply of electrical power to one or both of the processor and the digital to analog converter after disabling the clocking signal(s).

11. In a data processing system including a digital to analog converter and a data processor for operating on data received by the digital to analog converter, an adaptive data processing method, the method comprising the steps of:
monitoring the magnitude of data samples received from a data source; and
disabling one or both of the digital to analog converter and the data processor when the magnitude of the received signal falls within a predetermined magnitude range.

12. A method according to claim 11, further comprising the step of outputting the analog signal from the digital to analog converter to an output transducer to generate audible sound at a controllable output amplitude.

13. A method according to claim 12, further comprising the step of reducing the output amplitude of the output transducer prior to the step of disabling one or both of the data processor and the digital to analog converter.

14. A method according to claim 13, further comprising the step of controlling the gain of the amplifier to reduce the output amplitude of the output transducer.

15. A method according to claim 11, further comprising the step of disabling one or both of the data processor and the digital to analog converter when the magnitude of received data samples falls within a predetermined magnitude range over a predetermined time period.

16. A method according to claim 15, further comprising the step of re-enabling one or both of the data processor and the digital to analog converter when the magnitude of received data samples falls outside the predetermined magnitude range over the predetermined time period.

17. A method according to claim 15, wherein the predetermined time period is greater than the time period required to disable one or both of the data processor and the digital to analog converter.

18. A method according to claim 11, further comprising the step of disabling a clocking signal fed to one or both of the processor and the digital to analog converter in order to disabled by disabling one or both of the processor and the digital to analog converter.

19. A method according to claim 18, further comprising the step of disabling the supply of electrical power to one or both of the processor and the digital to analog converter after disabling the clocking signal(s).

20. A computer program residing on a computer-readable medium comprising instructions for causing a computer to perform an adaptive data processing method in a data processing system, the data processing system including an digital to analog converter and a data processor, the adaptive data processing method comprising the steps of:
monitoring the magnitude of data samples received from a data source, and
disabling one or both of the digital to analog converter and the data processor when the magnitude of the received signal falls within a predetermined magnitude range.
